(19) United States
(12) Patent Application Publication
(10) Pub. No.: US 2026/0372091 A1
(43) Pub. Date: Nov. 19, 2026

(54) Semiconductor Packaging System with Integrated Components and Connector Abundance

(71) Applicants: Cristian Penciu, Miami, FL (US); Andre Penciu, Dallas, TX (US)

(72) Inventors: Cristian Penciu, Miami, FL (US); Andre Penciu, Dallas, TX (US)

(21) Appl. No.: 19/463,055

(22) Filed: Jan. 28, 2026

Related U.S. Application Data
(60) Provisional application No. 63/751,816, filed on Jan. 30, 2025.

(51) Int. Cl. H10W 40/47; H10W 70/655; H10W 70/656; H10W 76/15

(52) U.S. Cl. CPC H10W 40/47; H10W 70/655; H10W 70/656; H10W 76/15

(57) ABSTRACT

An advanced semiconductor packaging system and methods of connecting dies and chiplets having an abundance of wires, high-bandwidth communication channels, and integrated passive components. In an embodiment, a packaging system comprises of thousands of Cu wires each having three orders of magnitude higher cross-sectional area than typical copper interconnects while achieving less than 15 micrometer pitch, thousands of integrated capacitors, inductors and resistors, features for efficient cooling, and integrated optical and dielectric RF waveguides and antennas. Methods of interconnecting the substrates for further package connectivity expansion as well as methods to adjust the value of the integrated passive components are described. In a particular embodiment, a dielectric RF waveguide ribbon is described that can be used for high bandwidth communication.

### CROSS-REFERENCE TO RELATED APPLICATIONS

This application claims priority to U.S. Provisional Application for Patent No. 63/751,816, filed Jan. 30, 2025, the contents of which are incorporated by reference in their entirety.

### BACKGROUND OF THE INVENTION

### Field of the Invention

Embodiments described herein relate to advanced semiconductor packaging. More particularly, embodiments relate to systems and methods of advanced packaging and substrates with integrated abundance of multi-type connectors for semiconductor Dies, 2.5D and 3D chiplets, and comprising integrated passive and active components.

### Background Information

Advanced packaging is crucial for improving semiconductor designs as it becomes more difficult to pack more transistors onto a single piece of silicon. The industry is moving to multi-die systems by putting together on the same package several integrated circuits (ICs) called chiplets that are either stacked or adjacent to one another (3D and 2.5D respectively). While this approach has many benefits such as better computational performance, increased functionality, and higher flexibility, it also creates significant challenges including a need for early partitioning and thermal planning, die/package co-design, robust die-to-die connectivity, as well as testing, system validation and overall reliability.

Interconnects are critically important for system performance and generally include both on-chip and off-chip interconnects in heterogeneous system integration. Silicon interposer, high-density fine-pitch fan-out redistribution layers (RDL), and bumpless bond are the three main current approaches to chip-to-chip interconnect on advanced heterogeneous integration technologies. Each interconnect technology is optimized for specific application and is closely associated with wafer-level heterogeneous integration technology such as CoWoS, InFO and SoIC. Data center interconnects, driven by the demands of AI and high-performance computing (HPC), are reaching the limits of bandwidth, power efficiency, and latency under current packaging architecture and technology. A good summary of the packaging technologies is provided by Li et al. , ‘High-Bandwidth Chiplet Interconnects for Advanced Packaging Technologies in AI/ML Applications: Challenges and Solutions,’ IEEE Open Journal of the Solid-State Circuits Society, December 2024, doi: 10.1109/OJSSCS.2024.3506694.

### BRIEF SUMMARY OF THE INVENTION

A semiconductor packaging module and methods to connect to chips are described. In an embodiment, the semiconductor packaging module comprises alternating layers of thin conductive material and dielectric material, alternating layers of resistive film and dielectric material, optical waveguides, dielectric RF waveguides, sockets for chips/chiplets/dies arranged substantially along receiver bays having channels for cooling. The semiconductor packaging module provides abundance of wires having three orders of magnitude larger cross section than typical interconnects at very small contact pitch, integrated passive components (resistors, inductors, and capacitors), and potential for a true plug-and-play system for dies and chips while reducing the need for vias, bridges, and interposers. The numerous advantages of the packaging module include: accessibility for testing and repairs, beach-front connectivity and power delivery, provides better cooling, minimizes thermal expansion mismatch issues, reduced power requirements, and shorter interconnects.

### BRIEF DESCRIPTION OF DRAWINGS

FIG. 1 is a schematic perspective view of an advanced semiconductor packaging module (MICCA) comprising multitude of integrated components, abundance of connectors, multiple cooling channels, and plurality of bays with discrete sockets for semiconductor dies and/or 2.5D and 3D chiplets in accordance with an embodiment.

FIG. 2A-2B are schematic side views of a bay and socket with a chiplet/die connected to the adjacent segments of a semiconductor packaging module.

FIG. 3 is a schematic top view of two MICCA packaging modules being connected to each other with an end-coupling module in accordance with an embodiment.

FIG. 4 is a schematic longitudinal side views of three MICCA packaging modules interconnected through vertical stacking in accordance with an embodiment.

FIG. 5 is a schematic side view across/end-view of three MICCA packaging modules interconnected through vertical stacking in accordance with an embodiment.

FIG. 6 is a schematic top view of cross-connector module illustrating connection redistributions between segments of the MICCA packaging module in accordance with an embodiment.

FIG. 7 is a schematic top view of a chip adapter module illustrating a connectivity method with adjacent segments of the MICCA packaging module for various chips in accordance with an embodiment.

FIG. 8 is a schematic top view of a chip adapter module illustrating a connectivity method with adjacent segments of the MICCA packaging module for various chips requiring fan-out connections in accordance with an embodiment.

FIG. 9 is a schematic top view of a chip adapter module illustrating a connectivity method with adjacent segments of the MICCA packaging module for various chips requiring fan-ins connections in accordance with an embodiment.

FIG. 10 is a perspective view of a MICCA module embodiment comprising substantially parallel multitude of tape wires, capacitive and/or inductive elements, dielectric RF waveguides and antennas, resistive elements, optical waveguides, chiplets, and empty chip sockets.

FIG. 11 is an enlarged view of area 200 in FIG. 10.

FIG. 12 is an enlarged view of area 208 in FIG. 10.

FIG. 13 is a schematic partial perspective view of a ribbon type RF conductor showing three waveguides and corresponding antennas in accordance with an embodiment.

FIG. 14 is a schematic top view showing a method of connecting multiple tape wires or resistive elements in series arrangement in accordance with an embodiment.

FIG. 15 is a schematic top view showing a method of connecting multiple tape wires or resistive elements in parallel arrangement in accordance with an embodiment.

### DETAILED DESCRIPTION OF THE INVENTION

The following Disclosure enables a person skilled in the art to make and use the subject matter disclosed herein. The general principles described herein may be applied to embodiments and applications other than those detailed above without departing from the spirit and scope of this Disclosure. This Disclosure is not intended to be limited to the embodiments shown but is to be accorded the widest scope consistent with the principles and features disclosed or suggested herein.

Advanced packaging and related capabilities, such as heterogeneous integration, are designed to increase all aspects of system performance by linking multi-component assemblies with large numbers of interconnects to achieve a degree of integration that blurs the line between chip and package. The invention described herein of a semiconductor packaging module with Multitude of Integrated Components and Connector Abundance (MICCA) has key attributes of advanced packaging such as high data rate communication capability and suitability for three-dimensional heterogeneous integration (3DHI) of 2.5 and 3D chiplets.

In various embodiments, description is made with reference to figures. However, certain embodiments may be practiced without one or more of these specific details, or in combination with other known methods and configurations. In the following description, numerous specific details are set forth, such as specific configurations, dimensions and processes, etc., in order to provide a thorough understanding of the embodiments. In other instances, well-known semiconductor processes and manufacturing techniques have not been described in particular detail in order to not unnecessarily obscure the embodiments. Reference throughout this specification to “one embodiment” means that a particular feature, structure, configuration, or characteristic described in connection with the embodiment is included in at least one embodiment. Thus, the appearances of the phrase “in one embodiment” in various places throughout this specification are not necessarily referring to the same embodiment. Furthermore, the particular features, structures, configurations, or characteristics may be combined in any suitable manner in one or more embodiments.

The terms “underneath”, “over”, “between”, “stacked”, and “on” as used herein may refer to a relative position of one layer with respect to other layers. One layer “underneath”, “over”, or “on” another layer or bonded “to” or in “contact” with another layer may be directly in contact with the other layer or may have one or more intervening layers. One layer “between” layers may be directly in contact with the layers or may have one or more intervening layers. Furthermore, the term “chip” or “device” as used herein may refer to semiconductor circuits, semiconductor Dies, 2.5D and 3D chiplets, or other substrates incorporating cross-connects or other passive or active components.

The described MICCA packaging module is a scalable, low cost, semiconductor packaging solution able to support modular functions that comprise common logic functionality such as CPU and GPU chiplets, application specific integrated circuits (ASICs), Field-Programmable Gate Arrays (FPGAs), chiplets, plurality of high bandwidth memory (HBM) and memory management functions for SRAM, DRAM, HBM control, cache control, communications functions such as Ethernet/PCIe/Optical/RF, system input/output, new functions necessary for scale-out and integration, or smaller modular functions made possible by scale-down.

In broad terms, MICCA packaging module comprises of multitude of sequential sections, said sections having a plurality of alternating layers of thin conductive material (Ex.: Copper) and dielectric material, alternating layers of resistive film (Ex.: Carbon) and dielectric material, optical waveguides, dielectric RF waveguides sized for the desired transmission frequency, sockets for chips/chiplets/dies arranged substantially along receiver bays, and channels under the sockets for cooling. For example, the dielectric material described herein comprises of glass, ceramic, or polymer.

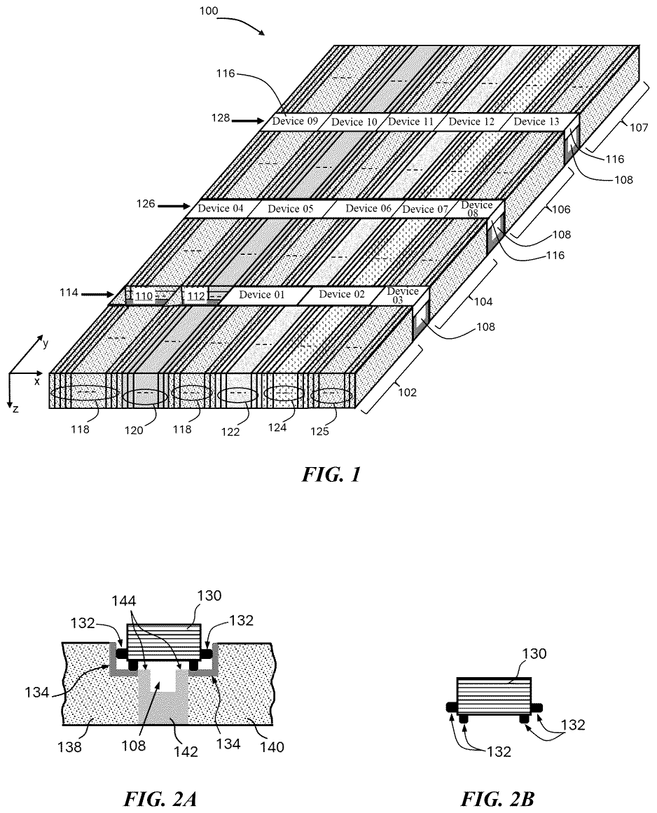

Referring to FIG. 1 a perspective view illustration of a MICCA semiconductor packaging module 100 and method of connecting chips is shown in an embodiment. The MICCA module extends in the indicated “Y” direction and the illustrated embodiment is separated in four segments 102, 104, 106, and 107, adjacent segments being separated by three chip receiver bays 114, 126, and 128. The receiver bays 114, 126, and 128 comprise of multitude of discrete chip sockets. The illustration in FIG. 1 shows as an example two unused chip sockets 110 and 112, and thirteen devices 116 (Devices 01-13) already installed in chip sockets. Only devices labeled 08, 09, and 13 are specifically pointed to in FIG. 1 to avoid cluttering of the drawing and facilitate readability.

The embodiment in FIG. 1 further comprises: channels 108 positioned substantially along the chip receiver bays and underneath the illustrated devices placed in their respective sockets, and said channels being suitable for liquid passing through for removing heat and cooling the chips; plurality of substantially parallel electrically conductive tape wires 118 (Ex.: Cu) alternating with dielectric film layers, and extending from the top surface to the bottom surface along the indicated “Z” direction of the MICCA module 100, and extending along the “Y” direction along each of the four segments 102, 104, 106, and 107; plurality of substantially parallel resistive film elements 120 alternating with dielectric film layers, extending from the top surface to the bottom surface along the indicated “Z” direction of the MICCA module 100, and extending along the “Y” direction along each of the four segments 102, 104, 106, and 107; plurality of optical waveguides 122 substantially parallel with each other extending from the top surface to the bottom surface along the indicated “Z” direction of the MICCA module 100, and extending along the “Y” direction along each of the four segments 102, 104, 106, and 107; plurality of dielectric radio-frequency (RF) waveguides and antennas 125 interleaved with tape wires, substantially parallel with each other and extending from the top surface to the bottom surface along the indicated “Z” direction of the MICCA module 100, and extending along the “Y” direction along each of the four segments 102, 104, 106, and 107; and a plurality of plates forming capacitive elements 124 interleaved with dielectric film layers substantially parallel with each other and extending from the top surface to the bottom surface along the indicated “Z” direction of the MICCA module 100, and extending along the “Y” direction along each of the four segments 102, 104, 106, and 107. Any two adjacent tape wires 118 separated by a dielectric film form a capacitor. Altogether, electrically conductive tape wires 118, optical waveguides 122, and dielectric RF waveguides and antennas, form a monolithic system of communication channels. The material of the chip receiver bays 114, 126, and 128 can electrically separate the four segments 102, 104, 106, and 107 from each other. While the embodiment of FIG. 1 shows, as an example, a sequence of six types of substantially parallel connectors and/or integrated component elements starting from left to right with tape wires 118, tape shaped resistive elements 120, tape wires 118, optical waveguides 122, tape shaped capacitive elements 124, and RF waveguides and antennas 125, it is to be understood that any sequence combination and number of elements within each type can be implemented. The mentioning of the interleaved dielectric layers is left out to simplify the description, but it is to be understood that each tape wire, resistive film element, and capacitive elements are separated by a dielectric film layer. Also, not all types of connectors or integrated components described herein have to be included, and the number of connector types in the sequence is not limited to six as illustrated in this particular embodiment. Furthermore, in other embodiments, for additional design flexibility and optimization, some of the tape wires can be ground planes (“ground” connection in electronics and electrical systems) serving to reduce signal cross-talk.

The ability to have an abundance (Ex.: tens of thousands) of electrically conductive tape wires 118 monolithically integrated in the MICCA module provide unprecedented opportunities for system designers, practically offering unlimited number of “bus” lines with many significant additional benefits. As transistor dimensions shrink, the interconnect cross-sectional area decreases leading to its resistance to increase dramatically, impacting device power and performance especially at very high frequencies. Due to the high aspect ratio (height to width size in “Z” and “X” directions respectively in FIG. 1), what is referred to as “tape wire” or “tape wires” throughout this Disclosure, it physically resembles the shape of vertical connector strips (VCS). VCS are a key feature of this Disclosure creating a much larger cross-sectional area (three orders of magnitude larger than current interconnect technology) for interconnections among chips resulting in significant benefits such as lower transmission losses leading to longer transmission distance with the same power budget, or less power needed for the same distance. Lower power needed leads to less heat generated and simpler heat management solutions while the increased surface area of the VCS leads to better heat dissipation.

Through proprietary manufacturing methods, the pitch of the tape wires can be tailored to the desired size including starting as low as below 1 micrometer. The material of the electrically conductive wire can be Copper (Cu), Silver (Ag), Gold (Au), or any other conductor or conductive alloy. The conductor width within the tape wire pitch can be customized as any percentage ranging between 10% and 90% of the tape wire pitch. As an example, a tape wire pitch of 10 micrometers, results in a MICCA module with 10,000 wires having a width of 10 cm. Another benefit of this Disclosure is provided by tape wires extending from the top (“XY” plane) surface to the bottom surface of the MICCA module, facilitate connectivity of chips or chiplets to be connected on both sides in an electrically parallel configuration at chip socket location to be placed on both sides in a parallel configuration (top and bottom of module 100) and/or at a plurality of depths in the “Z” direction of the MICCA semiconductor packaging module 100.

As an example of usage method, a chip socket (Ex.: 110 in FIG. 1) can hold both memory and logic chips placed stacked on top of each other and therefore making very short electrical connections through the tape wires 118 embedded into MICCA module. The current standard for the HBM4 memory stack requires 2,048-bit wide data interface and has an approximate footprint dimension of 10.5×12 mm, which is similar to some microprocessors. A MICCA module with 10 micrometer pitch for the tape wires would provide 1,200 connections (for 12 mm length), which is more than the 1,024 (half of the 2,048-bit wide data interface) connections needed by the HBM4 memory stack module, assuming beach-front connections on two sides.

While the current direction in hybrid bonding aims to further reduce the high-density Cu interconnection pitch for chiplet integration, it uses discrete structures such as Cu pillars and vias with ultra-small features (even at sub-micron scale) to achieve connectivity. This Disclosure illustrates a novel alternative that has a “bus” like architecture that offers many advantages. The embodiments in this Disclosure facilitate crucial functions and provide benefits including but not limited to:
a) ability to readily test the module and its Dies/chips/chiplets by having easy access to contacts along the top, bottom, or the ends (in “XZ” plane) of the MICCA module;
b) facilitate repairs by providing easy access to remove and replace chips;
c) opens-up design constraints at wafer and panel level packaging (WFL and PLP);
d) minimizes the substrate thermal expansion mismatch issue;
e) eliminates need for bridges and many manufacturing steps associated with RDL;
f) creates an ecosystem of true plug-and-play;
g) reduces or eliminates the need for discrete components such as resistors, capacitors or inductors;
h) minimizes parasitic capacitance occurring at ultra-fine Cu contacts pitch (sub-micron) by maintaining larger connector spacing;
i) allows chips to be placed directly onto the MICCA packaging module using solder or solderless connections such as direct metal-metal bonds (Ex.: Cu—Cu bonds, Au—Au bonds, etc.) leading to significantly reduced fabrication costs through reduction or elimination of complex physical interconnects employing interposers, through silicon vias (TSV), and micro bumps structures;
j) allows supplying power to silicon integrated circuits from the sides of the die additional to the typical front side of the chip presenting new possibilities for chip designers.

Further advantages of the MICCA module and its method of connecting chips are obvious to people skilled in the art of the subject matter described herein.

The plurality of resistive tape film elements 120 can be integrated within MICCA module 100 in the form of resistive layers comprising of metal film, metal oxide film, or carbon film alternating with a dielectric film material. Other suitable materials commonly employed can be used to form the resistive layer film. Connecting two or more resistor elements in series or parallel allows for multitude of resistor values to be obtained. MICCA module 100 can be connected to other systems or modules through the exposed contacts and connector terminations at the two ends (“XZ” planes) or through the exposed contacts and connectors on top and bottom surfaces (“XY” planes).

Looking from the side of a MICCA semiconductor packaging module 100 primarily at the location of a chip bay, FIG. 2A shows a schematic side view illustration of a chip bay and socket with a chiplet/die 130 inserted in it and said chiplet/die 130 being connected through multitude of electrical contacts 132 to the electric contact pads 134 of two adjacent segments 138 and 140 of a MICCA module. FIG. 2A further illustrates in an embodiment the landing pads 144 of the MICCA module for support and positioning (including depth) of the chips, the region 142 that electrically separates the two adjacent segments 138 and 140, and a cooling channel 108 under the chips. FIG. 2B is a separate view of chiplet/die 130 showing the side and bottom multitude of electrical contacts 132. The dual arrangement method of side and bottom contacts illustrated in the embodiment of FIG. 2B is particularly well suited for chiplets that have two-dimensional high density ball grid array (BGA) type of contacts on the bottom surface and/or “beach front” connectors (connectors on the side of the chip) on the side of the module.

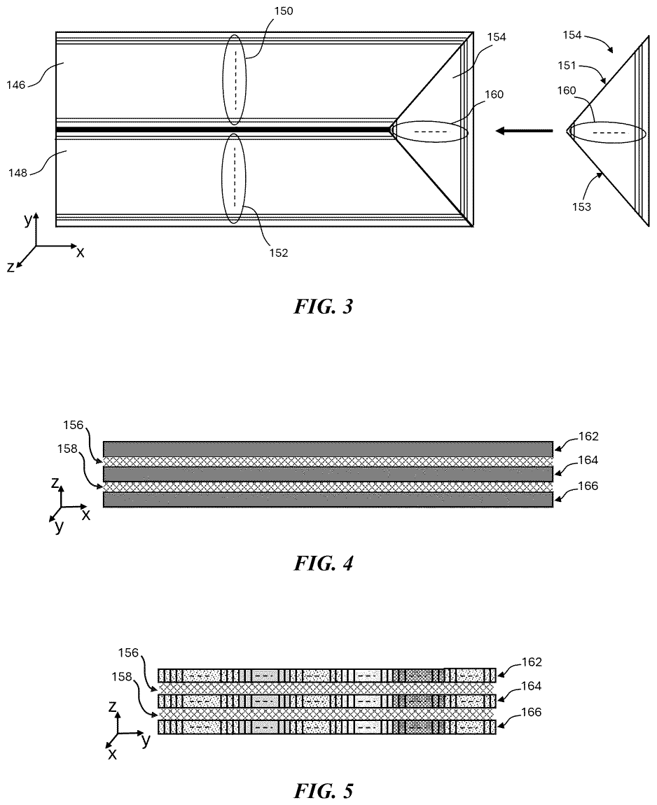

MICCA semiconductor packaging module 100 can be expanded by connecting multiple modules. FIG. 3 shows a schematic top view illustration of two MICCA modules 146 and 148 being connected to each other with an end-coupling module 154 that has substantially a triangular shape with sides 153 and 151 forming angles to match the diagonal cut angles of the modules 146 and 148. Furthermore, the sides 153 and 151 of the end-coupling module have contacts matching the corresponding side contacts of modules 146 and 148. The end-coupling module 154, being essentially a diagonal cross-cut of a MICCA module similar to 146 or 148, is shown in two positions, before and after connection to MICCA modules 146 and 148 with the arrow indicating the direction of motion between the two positions. The sequence of types and numbers of communication channels and passive elements 150, 152 and 160 substantially match each other to facilitate connectivity. To further clarify the connectivity among the two MICCA modules and the end-coupling module, as an example embodiment of FIG. 3, if the top part of module 146 incorporates 2,000 tape wires, then the end-coupling module 154 will also incorporate 2,000 tape wires on its right side in such a way that when module 146 and end-coupling module 154 are placed in contact, the 2,000 top tape wires of module 146 make contact with the right side of end-coupling module 154. Similar connectivity takes place between end-coupling module 154 and MICCA module 148 with the understanding that now the corresponding 2,000 tape wires will be located at the bottom of module 148 to match with the end-coupling module 154. It should be clear to anyone skilled in the art that a multitude of MICCA modules can be connected in this manner.

In yet another embodiments, FIG. 4 and FIG. 5 show two views in the “ZX” and “ZY” planes respectively of a stacking method for expanding to multitude of interconnected MICCA modules. In the embodiments of FIG. 4 and FIG. 5, three MICCA modules 162, 164, and 166 are interconnected through module connectors 156 and 158. Each of the connectors 156 and 158 can independently of each other connect all or selectively connect only desired numbers or portions of the tape wires (118 in FIG. 1), optical waveguides (122 in FIG. 1), dielectric RF waveguides (125 in FIG. 1), and passive elements (resistors, capacitors, inductors) of modules 162, 164, and 166.

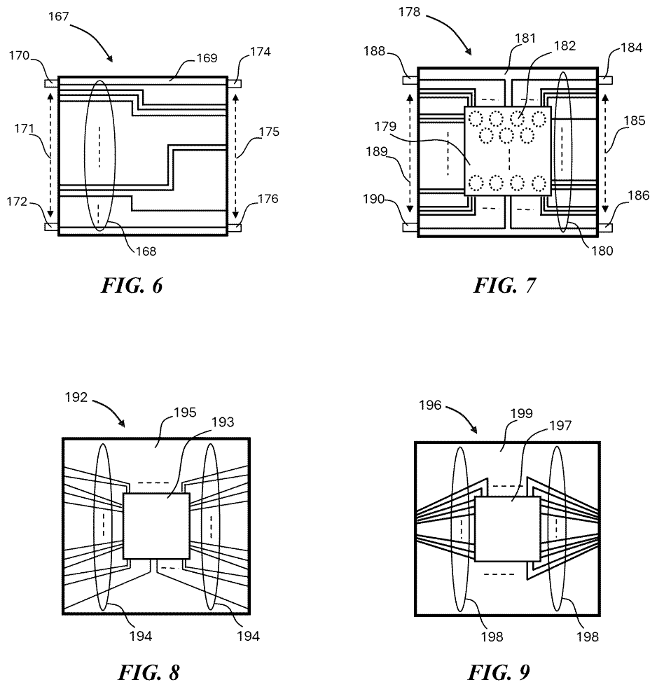

The design flexibility at the system level offered by the MICCA packaging module and examples of methods of connectivity are illustrated in FIGS. 6-9.

FIG. 6 illustrates a cross-connector module (XCON) 167 comprising a dielectric substrate 169, a multitude of connectors 168 placed onto or integrated into the dielectric substrate, and coupling contacts 170, 172, 174, and 176. Connectors 168 can be pass through electrical connections between adjacent segments (Ex.: 104 and 106 of FIG. 1) either straight from first segment to the corresponding connector on the second segment or routed from any connector of the first segment to any connector on the second segment. While only two coupling contacts 170 and 172 are specifically identified on the left side of FIG. 6, it is to be understood that there are a multitude of coupling contacts spanning between said two coupling contacts represented by dashed arrow 171 that correspond to contacts to one segment (Ex.: 104 of FIG. 1). Similarly on the right side of FIG. 6, while only two coupling contacts 174 and 176 are specifically identified, it is to be understood that there are a multitude of coupling contacts spanning between said two coupling contacts represented by dashed arrow 175 corresponding to contacts to one segment (Ex.: 106 of FIG. 1). Interconnections between adjacent segments can be made on both surfaces and sides of substrate 169, and also multiple substrates can be stacked for additional connections flexibility.

FIG. 7 illustrates a method of using a chip adapter module to connect between two adjacent segments (Ex.: 104 and 106 of FIG. 1). The chip adapter module 178 comprises of a dielectric substrate 181, a chip 179 with BGA type connectors 182, connectors 180 leading from chip 179 contacts to two “beach front” sides, and a plurality of coupling contacts on the left and right sides of the chip adapter module 178. While only two coupling contacts 188 and 190 are specifically identified on the left side of the chip adapter module 178 in FIG. 7, it is to be understood that there are a multitude of coupling contacts similar to and spanning between coupling contacts 188 and 190 that are represented by dashed arrow 189 with said multitude of coupling contacts being in contact with a segment of MICCA module (Ex.: 104 of FIG. 1). Similarly on the right side of the chip adapter module 178 in FIG. 7, while only two coupling contacts 184 and 186 are specifically identified, it is to be understood that there are a multitude of coupling contacts similar to and spanning between coupling contacts 184 and 186 that are represented by dashed arrow 185 with said multitude of coupling contacts being in contact with a segment (Ex.: 106 of FIG. 1) of MICCA module.

FIG. 8 illustrates a method of using a chip adapter module 192 to connect between two adjacent segments (Ex.: 104 and 106 of FIG. 1). The chip adapter module 192 comprises of a dielectric substrate 195, a chip 193, and fan-outs 194 (spreading apart of high-density chip connectors). Chip 193 can have BGA type connectors and/or beach front connectors to attach to the chip adapter module. For drawing clarity and simplicity, the additional embodiment features presented in FIG. 6 and FIG. 7 are not replicated again in FIG. 8, but that is not to be taken as a limitation of this Disclosure, instead it is to be understood that it is possible to combine any or all features presented in FIGS. 6-9 into a single embodiment.

FIG. 9 illustrates a method of using a chip adapter module to connect between two adjacent segments (Ex.: segments 104 and 106 of FIG. 1). The chip adapter module 196 comprises of a substrate 199, a chip 197, and fan-ins 198 chip connectors (reducing spacing between connectors at the side of the chip adapter module). Chip 197 can have BGA type connectors and/or beach front connectors to attach to the chip adapter module. While only one chip is shown for illustration simplicity in the embodiments of FIGS. 7-9 as an example, it is to be understood that multiple chips can be located and interconnected on a chip adapter module.

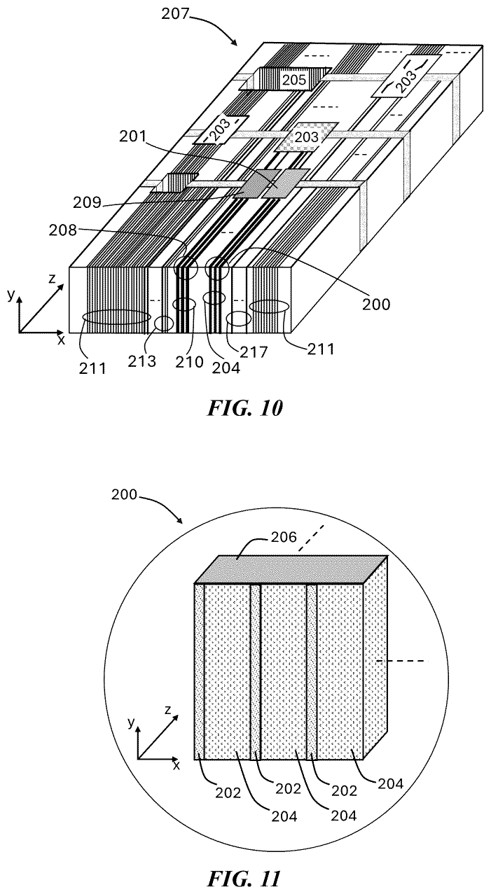

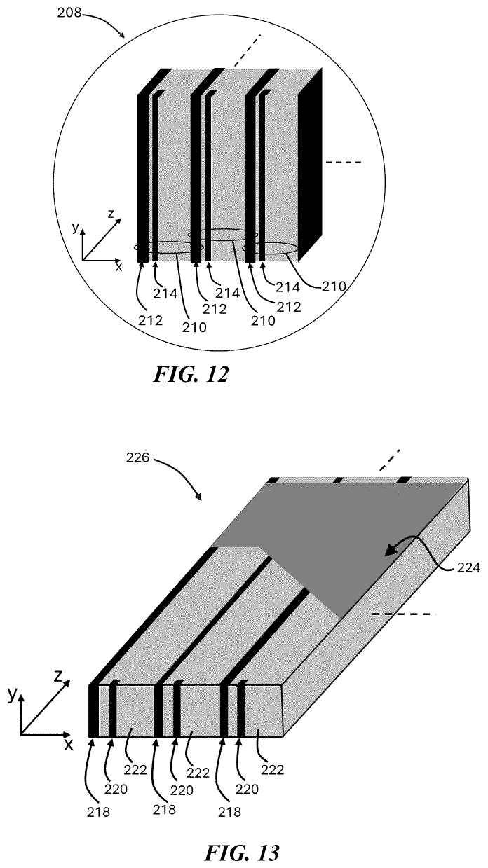

FIG. 10 shows a perspective view of an embodiment of MICCA module 207 comprising substantially parallel multitude of tape wires 211, substantially parallel capacitive or inductive elements 213, substantially parallel dielectric RF waveguides and antennas 210, substantially parallel resistive elements 217, substantially parallel optical waveguides 204, three chips 203, chip 201 connected to optical waveguides, chip 209 connected to dielectric RF waveguides 210, empty chip socket 205, areas 200 and 208 that are enlarged in FIG. 11 and FIG. 12 respectively.

FIG. 11 illustrates a magnified schematic perspective end-view 200 of a partial MICCA module embodiment comprising of three integrated optical waveguides 204 substantially parallel to each other, three layers 202 with lower index of refraction separating the waveguides 204, a layer 206 on top and bottom surfaces of the waveguides structure (bottom layer not visible in FIG. 11). The three layers 202 with lower index of refraction are not needed if the optical waveguided has graded index construction. In one embodiment the optical waveguides 204 extend in the “Z” direction for the entire length of MICCA module 207, and yet in another embodiment the waveguides 204 extend for a shorter distance as needed for a particular embodiment. Referring to optical waveguides 204, the term “optical waveguide” should be interpreted in the broadest sense to include all types of optical waveguides comprising single mode, multimode, step index or graded index. Furthermore, the integrated optical waveguides 204 can comprise side gratings for coupling signals into and out of the waveguides and for monitoring of the optical channel functions, and can also have exposed endings for coupling to connectors (not shown) or other systems capable of receiving and/or transmitting optical communication from and/or into the waveguide. Coupling signals into and out of the optical waveguides 204 can be accomplished in accordance with any other known methods described in relevant art. The top layer 206 and the bottom layer in one embodiment can be made of an optically absorbing material or a reflective material in another embodiment. It is implied that the number of optical waveguides can be increased as needed in “X” direction.

FIG. 12 illustrates a magnified schematic perspective end-view 208 of a partial MICCA embodiment comprising three dielectric RF waveguides 210 substantially parallel to each other and associated antennas 214, separated by three conductive tape wires 212 in an embodiment. In one embodiment the RF waveguides 210 and conductive tape wires 212 extend in the “Z” direction for the entire length of MICCA module 100, and yet in another embodiment the waveguides 210 and tape wires 212 extend for a shorter distance as needed for a particular embodiment. A top and bottom conductive surface layer can be made along the RF waveguides to create in essence rectangular tubing surrounding the dielectric material of the waveguide. Coupling signals into and out of the RF waveguides 210 can be accomplished in accordance with any known methods described in relevant art. It is implied in this Disclosure that the number of RF waveguides can be increased as needed in “X” direction.

A simplified embodiment of MICCA module 100 of FIG. 1 is illustrated in FIG. 13. The embodiment illustrated in FIG. 13 shows a schematic partial perspective end-view of a RF waveguides ribbon 226 comprising of three substantially parallel dielectric RF waveguides 222 and associated antennas 220, separated by three conductive tape wires 218 in accordance with an embodiment. A partial view of the top metallic film or coating 224 (Ex.: Cu) extending over the entire top and bottom area of the RF waveguides ribbon 226 is also shown (top film only). It is implied in this Disclosure that the number of RF waveguides in the ribbon structure can be increased as needed in “X” direction and the length of the ribbon can be extended in “Z” direction.

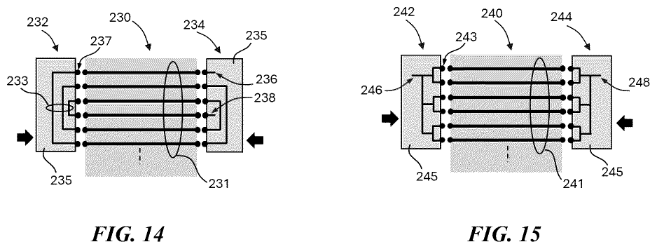

Referring to FIG. 14, it shows a schematic illustration of a partial top view comprising a MICCA module segment 230 (could be any of the four segments 102, 104, 106, and 107 illustrated in FIG. 1), six substantially parallel tape wires 231 integrated in segment 230, dielectric substrates 235, side connectors 237, and connector modules 232 and 234 having the side connectors pitch spacing the same as the tape wires 231. FIG. 14 further shows a method of connecting the tape wires of segment 230 in series using tape wires interconnections 233. When connector modules 232 and 234 are moved (in the directions of the two arrows) to make contact with the tape wires of segment 230, the side connectors 237 of connector modules 232 and 234 make contact with segment 230 resulting in the tape wires 231 forming primarily a flat inductor structure or primarily a capacitor structure depending on the geometric dimensions of segment 230. As an example, if the width of segment 230 is shorter, then the structure of the connected tape wires behaves more as an inductor. Increasing the width of segment 230 above a certain value, the structure behaves more as a capacitor. In another embodiment, if the tape wires 231 are substituted by resistive film elements, resistors with larger values can be created. In this embodiment, connector module 234 comprises both the starting point connection 236 and the end point connection 238 of the newly formed flat inductor or capacitor structure, or the connecting end points of the larger resistor formed if resistive film elements are connected through this method.

Referring to FIG. 15, it shows a schematic illustration of a partial top view comprising a MICCA module segment 240 (could be any of the four segments 102, 104, 106, and 107 illustrated in FIG. 1), six substantially parallel tape wires 241, dielectric substrates 245, side connectors 243, and connector modules 242 and 244 that have the side connectors pitch spacing the same as the tape wires 241. FIG. 15 further shows a method of connecting the tape wires of segment 240 in parallel when connector modules 242 and 244 are moved (in the directions of the two arrows) to make contact with the tape wires of segment 240. When the side connectors 243 of connector modules 242 and 244 make contact with segment 240, the tape wires 241 form substantially a larger capacitor structure in accordance with an embodiment. In another embodiment, if the tape wires 241 are substituted by resistive tape film elements, then resistors with smaller values can be created. In the embodiment of FIG. 15, connector module 246 comprises one end point of the connection (Ex.: starting point), while connector module 248 comprises the second end point of the connection.

While this Disclosure primarily describes systems and methods related to high density physical layer interconnects between chips and/or chiplets, there is no requirement for any such limitation. After reading this Disclosure, those skilled in the art will recognize that the techniques described herein are applicable to a wide variety of devices disposed to interconnect electronic circuitry or portions thereof. For example, the techniques described herein are applicable to a wide variety of different types of devices placed to interconnect electronic circuitry or portions thereof, and to provide high-bandwidth interconnects therebetween; or otherwise as described herein. Moreover, those skilled in the art will recognize that the techniques described herein are applicable to a wide variety of different types of devices which can computing devices, memory devices, specialized hardware/software devices such as tensor processing devices (TPUs), video processing devices (VPUs), and a wide variety of different types of electronic circuitry coupling.

Although the embodiments have been described in language specific to structural features and/or methodological acts, it is to be understood that the appended claims are not necessarily limited to the specific features or acts described. The specific features and acts disclosed are instead to be understood as embodiments of the claims useful for illustration.

What is claimed is:

1. A three-dimensional (3D) packaging system comprising:
a plurality of substantially parallel communication channels forming a monolithic system, each communication channel extending completely from one side to the opposite side across the 3D packaging system;
a plurality of substantially parallel alternating layers of resistive film elements and dielectric material incorporated into the monolithic system, each resistive film element extending completely from one side to the opposite side across the 3D packaging system;
a plurality of chip receiver bays extending across the monolithic system, electrically separating the monolithic system into a plurality of segments;
a plurality of cooling channels extending along said chip receiver bays; and
a plurality of chip sockets located in said chip receiver bays, each chip socket having access to the communication channels of adjacent said segments.

2. The 3D packaging system of claim 1, wherein the communication channels comprise alternating layers of electrically conductive wires and dielectric material.

3. The 3D packaging system of claim 2, wherein the electrically conductive wires have substantially the geometric shape of a tape.

4. The 3D packaging system of claim 1, wherein the communication channels comprise optical waveguides.

5. The 3D packaging system of claim 4, wherein said optical waveguides comprise means to couple signals into and out of the optical waveguides.

6. The 3D packaging system of claim 1, wherein the communication channels comprise of dielectric RF waveguides and antennas.

7. The 3D packaging system of claim 6, wherein said dielectric RF waveguides and antennas comprise means to couple signals into and out of the dielectric RF waveguides and antennas.

8. The 3D packaging system of claim 1, wherein said chip sockets comprise electrical contact pads and landing pads.

9. The 3D packaging system of claim 1, wherein said resistive film elements substantially have the geometric shape of a tape.

10. The 3D packaging system of claim 1, wherein said chip sockets are sized for tight fitting of chiplets.

11. The 3D packaging system of claim 1, wherein said chip sockets are sized for tight fitting of a plurality of semiconductor dies in a stacked configuration.

12. The 3D packaging system of claim 1, wherein end-coupling modules connect a plurality of 3D packaging systems.

13. The 3D packaging system of claim 1, wherein a plurality of 3D packaging systems are stacked and connected to each other with module connectors.

14. A chip adapter module comprising:
a dielectric substrate sized to fit tightly in a chip socket possessing a plurality of communication channels;
a plurality of interconnects leading to side connectors matching the pitch of the communication channels;
a plurality of fan-out interconnects;
a plurality of fan-in interconnects.

15. The chip adapter module of claim 12, wherein said dielectric substrate comprises a plurality of chips.

16. A method of interconnecting chips comprising:
a) integrating a plurality of alternating tape wires and dielectric films with a plurality of optical waveguides, and a plurality of dielectric RF waveguides to form a monolithic substrate;
b) creating a plurality of chip receiver bays across the monolithic substrate;
c) forming a plurality of chip sockets with electrical contact pads and landing pads in the chip receiver bays;
d) providing cooling channels along the chip receiver bays;
e) placing a first chip in a chip socket followed by a plurality of successive chips stacked on top of the first chip;
f) supplying power to chips through side contacts;
g) providing a plurality of access points for testing.

17. The method of claim 16, further comprising placing chip adapter modules and cross-connect modules in a chip socket.

18. The method of claim 16, further comprising coupling signals into and out of the optical waveguides.

19. The method of claim 16, further comprising coupling signals into and out of the dielectric RF waveguides.

20. The method of claim 16, further comprising connecting conductive tape wires to form inductors.
